(19) United States
(12) Patent Application Publication
(10) Pub. No.: US 2009/0059111 A1
(43) Pub. Date: Mar. 5, 2009

(54) LCD DRIVER IC AND METHOD FOR MANUFACTURING THE SAME

(76) Inventor: DUCK KI JANG, Gyeonggi-do (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/198,188

(22) Filed: Aug. 26, 2008

(30) Foreign Application Priority Data
Aug. 31, 2007 (KR) 10-2007-0088245

(51) Int. Cl. G02F 1/136; H01L 21/336

(52) U.S. Cl. 349/46; 438/305; 257/E21.409

(57) ABSTRACT

Disclosed is an LCD driver IC. The LCD driver IC can include a first conductive type well formed in a substrate, a second conductive type drift region formed in the first conductive type well, a first isolation layer formed in the second conductive type drift region, a gate formed on the substrate at a first side of the first isolation layer, and a second conductive type first ion implantation region formed in the second conductive type drift region between the first isolation layer and the gate.

### CROSS-REFERENCE TO RELATED APPLICATION

The present application claims the benefit under 35 U.S.C. §119 of Korean Patent Application No. 10-2007-0088245, filed Aug. 31, 2007, which is hereby incorporated by reference in its entirety.

### BACKGROUND

An LDI is a liquid crystal display (LCD) driver integrated circuit (IC). The LDI controls each section of a screen of an LCD that is divided into a plurality of sections. Several LDIs are generally used for each panel.

A power IC operating at a high voltage requires a high level of current. LDIs often include power ICs.

However, a high voltage IC, which may serve as the power IC requiring a high level of current, has a large size and high leakage level.

Reducing the size and the high leakage level of the high voltage IC may lower current performance.

The current performance of the high voltage IC may be lowered because current density becomes low in a drift region, which is formed for the purpose of Resurf (Reduce surface field), due to a low dose rate of the drift region.

Thus, there exists a need in the art for an improved power IC.

### BRIEF SUMMARY

Embodiments of the present invention provide an LCD driver IC having a small size, which can achieve high current performance, and a method for manufacturing the same.

An LCD driver IC according to an embodiment includes a first conductive type well formed in a substrate, a second conductive type drift region formed in the first conductive well, a first isolation layer formed in the second conductive type drift region, a gate formed on the substrate at a first side of the first isolation layer, and a second conductive type first ion implantation region formed in the second conductive drift region between the first isolation layer and the gate.

A method for manufacturing an LCD driver IC according to an embodiment can include: forming a first conductive type well in a substrate, forming a second conductive type drift region in the first conductive well, forming a first isolation layer in the second conductive type drift region, forming a gate on the substrate at a first side of the first isolation layer, and forming a second conductive type first ion implantation region in the second conductive drift region between the first isolation layer and the gate.

### BRIEF DESCRIPTION OF THE DRAWINGS

FIG. 1 is a cross-sectional view of an LCD driver IC according to an embodiment of the present invention.

FIGS. 2 and 3 are cross-sectional views showing a procedure for manufacturing an LCD driver IC according to an embodiment of the present invention.

### DETAILED DESCRIPTION

Hereinafter, embodiments of a method for manufacturing an LCD driver IC will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

In the following description, a first conductive type is referred to as a P-type and a second conductive type is referred to as an N-type. However, the scope of the present invention is not limited thereto.

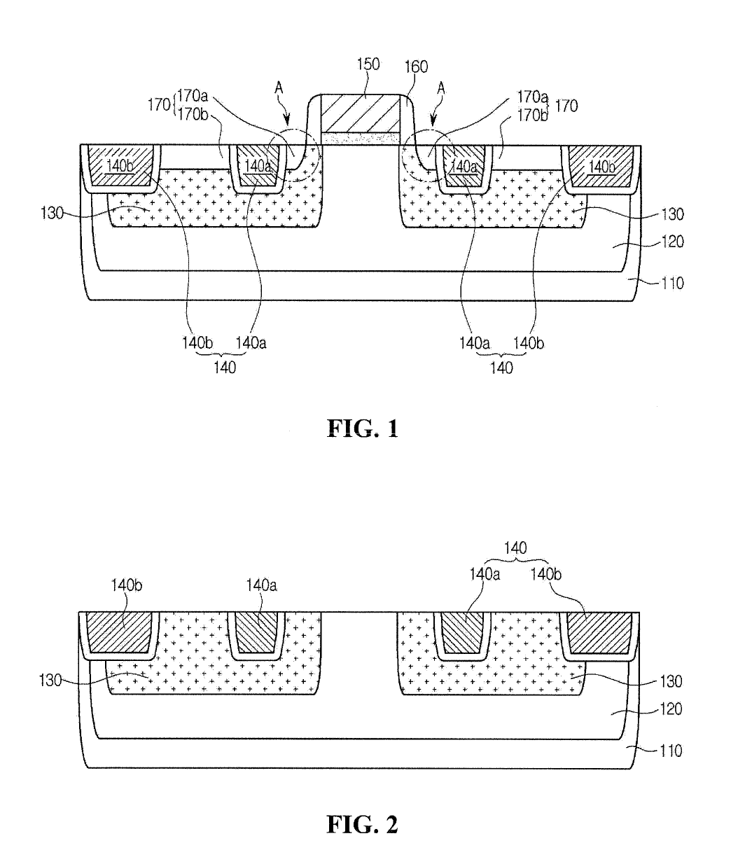

Referring to FIG. 1, an LCD driver IC according to an embodiment includes a first conductive type well 120 formed in a substrate 110, a second conductive type drift region 130 formed in the first conductive well 120, a first isolation layer 140a formed in the second conductive type drift region 130, a gate 150 formed at one side of the first isolation layer 140a, and a second conductive type first ion implantation region 170a formed in the second conductive type drift region 130 between the first isolation layer 140a and the gate 150.

In a further embodiment, the LCD driver IC can include a second conductive type second ion implantation region 170b formed in the second conductive type drift region 130 at the other side of the first isolation layer 140a. Thus, a second conductive type ion implantation region 170 can be provided, including the second conductive type first ion implantation region 170a and the second conductive type second ion implantation region 170b.

A spacer 160 can be formed at the lateral sides of the gate 150.

In addition, a second isolation layer 140b can be formed adjacently to the first conductive type well 120 and the second conductive type drift region 130. The second isolation layer 140b can be formed around the second conductive type drift region 150 at the edge of the first conductive type well 120. Thus, an isolation layer 140 can be provided, including the first isolation layer 140a and the second isolation layer 140b.

According to an embodiment, the first isolation layer 140a can be formed in the channel direction of the drift region 130, so that a current path formed in the substrate can be substantially increased. Thus, the small drift region can serve as the great drift region.

In detail, the size of a power IC can be reduced by forming the first isolation layer 140a in the channel direction of the drift region 130 serving as a source or a drain at a high voltage.

Thus, the drift region 130 can serve as reduce surface field (Resurf). At this time, the small drift region may serve as a great drift region. In detail, current flows through the surface of the silicon substrate and the isolation layer is formed on the substrate such that the current path on the surface of the substrate can be increased, thereby enabling the small drift region to serve as a great drift region.

Further, the first isolation layer is provided in the region in which the electric field is formed, thereby distributing the electric field.

According to an embodiment, a high concentration ion implantation region 170a “A” is formed in the drift region 130 between the first isolation layer 140a and the gate 150, so that the current density of the high voltage IC can be increased. Thus, high current performance of the high voltage IC can be ensured.

In detail, when forming the high concentration ion implantation region 170a, a device for the power IC is formed. According to the high voltage IC of the prior art, high concentration ion implantation regions HN+ and HP+ are limitedly formed in a predetermined area.

However, according to an embodiment, the N type or P type region of the high voltage device is open such that the high concentration ion implantation region can be formed therein. That is, a narrowly defined exposed region for implantation is no longer necessary.

For example, the high concentration ion implantation region (N+ or P+, 170) can be formed in the N type or P type region by using the spacer 160 formed at the lateral side of the gate 150 as a buffer.

That is, in the junction profile as shown in FIG. 1, a high concentration ion implantation region can be formed in the region “A”, so that the high current density of the power IC can be ensured. According to the prior art, the current density becomes low due to a low dose of ions in the drift region. However, according to embodiments of the present invention, the high concentration ion implantation region is formed in the region “A”, so that the current density can be increased.

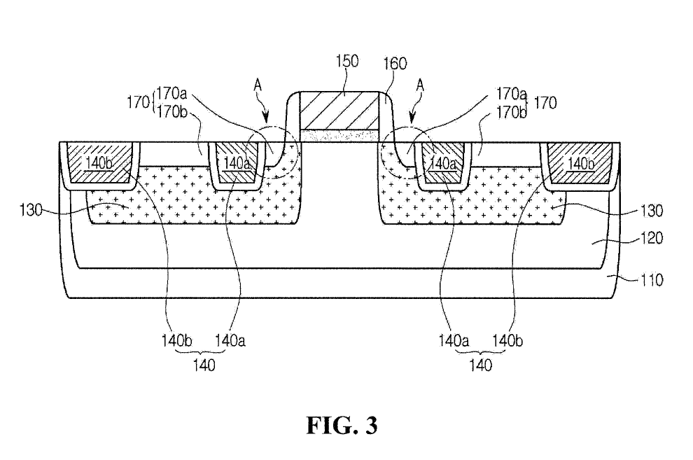

Hereinafter, a method for manufacturing an LCD driver IC according to an embodiment will be described with reference to FIGS. 2 and 3.

Referring to FIG. 2, a first conductive type well 120 can be formed in the substrate 110. For example, P type ions can be implanted into the substrate 110 and then driven in to form the high voltage P well 120.

Next, a second conductive type drift region 130 can be formed in the first conductive type well 120. For example, N type ions can be implanted into the P well 120 and then driven in to form the high voltage N type drift region 130.

Then, an isolation layer 140 can be formed. The isolation layer 140 can include a first isolation layer 140a formed in the second conductive type drift region 130 and a second isolation layer 140b at an edge of the second conductive type drift region 130.

The isolation layer 140 can be formed using, for example, a shallow trench isolation (STI) process.

According to an embodiment, the first isolation layer 140a can be formed in the channel direction of the drift region 130, so that the current path formed in the substrate can be substantially increased. Thus, the small drift region can serve as the great drift region.

Then, referring to FIG. 3, a gate 150 can be formed at a side of the first isolation layer 140a. For example, the gate 150 can be formed on the first conductive type well 120 of a region adjacent to the second conductive type drift region 130.

Next, a spacer 160 can be formed at the lateral sides of the gate 150.

A second conductive type high concentration ion implantation region 170 can be formed by implanting ions into the substrate using the spacer 160 as a buffer.

For example, by implanting the second conductive type ions into the substrate, the second conductive type first ion implantation region 170a can be formed in the second conductive type drift region 130 between the first isolation layer 140a and the gate 150.

Further, a second conductive type second ion implantation region 170b can be formed in the second conductive type drift region 130 at the other side of the first isolation layer 140a.

At this time, the second conductive type first ion implantation region 170a and the second conductive type second ion implantation region 170b can be simultaneously or sequentially formed.

According to an embodiment, the high concentration ion implantation region 170a “A” is formed in the drift region 130 between the first isolation layer 140a and the gate 150, so that the current density of the high voltage IC can be increased. Thus, the high current performance of the high voltage IC can be ensured.

According to embodiments of the LCD driver IC and the method for manufacturing the same, an isolation layer is further formed in the channel direction of the drift region, so that the current path formed in the substrate can be substantially increased, thereby enabling the small drift region to serve as the great drift region.

Further, according to an embodiment, the high concentration ion implantation region is formed in the drift region between the isolation layer and the gate, so that the current density of the high voltage IC can be increased. Thus, the high current performance of the high voltage IC can be ensured.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An LCD driver IC comprising:
a first conductive type well in a substrate;
a second conductive type drift region in the first conductive well;
a first isolation layer in the second conductive type drift region;
a gate on the substrate at a first side of the first isolation layer; and
a second conductive type first ion implantation region in the second conductive type drift region between the first isolation layer and the gate.

2. The LCD driver IC according to claim 1, further comprising a second conductive type second ion implantation region in the second conductive type drift region at a second side of the first isolation layer.

3. The LCD driver IC according to in claim 1, further comprising a spacer at a lateral side of the gate.

4. The LCD driver IC according to claim 1, wherein the second conductive type first ion implantation region comprises a high concentration of second conductive type ions.

5. A method for manufacturing an LCD driver IC, comprising:
forming a first conductive type well in a substrate;
forming a second conductive type drift region in the first conductive type well;
forming a first isolation layer in the second conductive type drift region;
forming a gate on the substrate at a first side of the first isolation layer; and
forming a second conductive type first ion implantation region in the second conductive type drift region between the first isolation layer and the gate.

6. The method according to claim 5, further comprising, after forming the gate, forming a second conductive type second ion implantation region in the second conductive type drift region at a second side of the first isolation layer.

7. The method according to claim 6, wherein the second conductive type first ion implantation region and the second conductive type second ion implantation region are simultaneously formed.

8. The method according to claim 5, further comprising forming a spacer at a lateral side of the gate.

9. The method according to claim 8, wherein forming the second conductive type first ion implantation region comprises performing an ion implantation process by using the spacer as a buffer.
